(19) United States
(12) Patent Application Publication
(10) Pub. No.: US 2024/0126952 A1
(43) Pub. Date: Apr. 18, 2024

(54) ARITHMETIC OPERATION SYSTEM, TRAINING METHOD, AND NON-TRANSITORY COMPUTER READABLE MEDIUM STORING TRAINING PROGRAM

(71) Applicant: NEC Corporation, Tokyo (JP)

(72) Inventors: Tsubasa NAKAMURA, Tokyo (JP); Jiro ABE, Tokyo (JP)

(73) Assignee: NEC Corporation, Tokyo (JP)

(21) Appl. No.: 18/375,663

(22) Filed: Oct. 2, 2023

(30) Foreign Application Priority Data
Oct. 12, 2022 (JP) 2022-163698

(51) Int. Cl. G06F 30/27; G01S 7/4865; G01S 17/10

(52) U.S. Cl. CPC G06F 30/27; G01S 7/4865; G01S 17/10

(57) ABSTRACT

In an arithmetic operation system, an evaluation unit calculates a difference amount between a teaching signal and an estimated signal. The teaching signal is a spatial distribution signal observed with respect to a spatial structure on a path of an emission wave in a target space (i.e., a teaching space) by using the emission wave. In addition, the estimated signal is a signal for comparing with the teaching signal, and is an estimated spatial distribution signal. The estimated signal is formed based on estimated density associated to each sample point acquired from a spatial estimation model, by a sampling unit inputting information about a position of each of a plurality of sample points on the path to the spatial estimation model. An updating unit updates the spatial estimation model, based on the difference amount.

### INCORPORATION BY REFERENCE

This application is based upon and claims the benefit of priority from Japanese patent application No. 2022-163698, filed on Oct. 12, 2022, the disclosure of which is incorporated herein in its entirety by reference.

### TECHNICAL FIELD

The present disclosure relates to an arithmetic operation system, a training method, and a training program.

### BACKGROUND ART

Light detection and ranging (LiDAR) is known as an optical observation system capable of acquiring three-dimensional depth information. Currently, in general, a LiDAR can acquire distance information by applying a ray (a light beam) toward a subject and utilizing information such as a round trip time of a ray (reflected light) reflected from the subject or a phase difference of an optical signal. Light reflected from the subject is widely diffused into a space. Therefore, in order to determine a direction (a horizontal direction and a vertical direction) in which the subject is present, for example, a scanner is driven, or angle resolution using an optical system is performed. As a result, direction information of the subject is acquired. With these combinations, a LiDAR can acquire three-dimensional information.

In addition, a spatial estimation system for estimating a three-dimensional space has been proposed (for example, Non Patent Literature 1 (Ben Mildenhall, Pratul P. Srinivasan, Matthew Tancik, Jonathan T. Barron, Ravi Ramamoorthi, Ren Ng, “NeRF: Representing Scenes as Neural Radiance Fields for View Synthesis”, ECCV 2020 (Oral), [searched on Oct. 7, 2022], the Internet <URL:https://arxiv.org/pdf/2003.08934.pdf>), and Non Patent Literature 2 (Konstantinos Rematas, Andrew Liu, Pratul P. Srinivasan, Jonathan T. Barron, Andrea Tagliasacchi, Thomas Funkhouser, Vittorio Ferrari, “Urban Radiance Fields”, CVPR 2022, [searched on Oct. 7, 2022], the Internet <URL:https://arxiv.org/pdf/2111.14643.pdf>)). Non Patent Literature 1 discloses a technique referred to as “representing scenes as neural radiance fields for view synthesis (NeRF)”, which is a kind of “differentiable rendering” and trains an object density distribution function in a space by using a framework of deep learning. According to the technique, a training model can train a three-dimensional structure of a subject by using an image being captured from multiple viewpoints as a teacher. The model after training can generate an image of a viewpoint when new viewpoint information is input.

In addition, Non Patent Literature 2 discloses a method in which a method referred to as the “NeRF” in Non Patent Literature 1 and a LiDAR are combined with each other. According to the technique disclosed in Non Patent Literature 2, depth information of a subject being acquired from the LiDAR can be applied to a training framework similar to that of Non Patent Literature 1, and thereby a spatial structure (spatial distribution) can be trained.

Herein, a training method and a training model of the “NeRF” are classified into one of wider framework methods referred to as “differentiable rendering”. The “NeRF” is a designation in Non Patent Literature 1, but a large number of derivative techniques of the technique have been reported in recent years. Among the derivative techniques, a training model that does not use a neural network layer but utilizes only a framework of deep learning is included, and the training model also achieves a similar function to the “NeRF”. For this reason, a “radiance field (hereinafter, described in “RF”)” may be used as more abstract representation including the training models in the present disclosure. In other words, in the present disclosure, the training model is not limited to multi layer perceptron (MLP) adopted in the NeRF.

The present inventor has found that, in the techniques disclosed in Non Patent Literatures 1 and 2, there is a possibility that spatial training is not efficiently performed. For example, in the techniques of Non Patent Literatures 1 and 2, there is an operation of line-integrating a density distribution on a path of a ray in a process of “rendering” of a certain pixel. Then, at a time of the operation, information in a distance direction is compressed into information on one point (in other words, zero-dimensional information). Therefore, abundant information distributed in an original distance direction cannot be effectively utilized. That is, the techniques in Non Patent Literatures 1 and 2 do not sufficiently utilize information acquired by one sensor (a camera, a LiDAR).

### SUMMARY

An example object to be achieved by example embodiments disclosed in the present description is to provide an arithmetic operation system, a training method, and a training program that contribute to solving at least one of a plurality of problems including the problems described above. Note that, it should be paid attention that the object is merely one of a plurality of objects to be achieved by a plurality of example embodiments disclosed in the present description. Other objects or problems and novel features will be apparent from the description of the present description or the accompanying drawings.

In a first example aspect, an arithmetic operation system includes:
an acquisition unit configured to acquire, as a teaching signal, a spatial distribution signal observed by a sensor with respect to a spatial structure on a path of an emission wave by using the emission wave;
a sampling unit configured to input information about a position of each of a plurality of sample points on the path to a spatial estimation model, and acquire, from the spatial estimation model, estimated density related to a probability that an object emitting the emission wave from the plurality of sample points is present;
a forming unit configured to form an estimated signal for comparing with the teaching signal, based on information about a position of each of the plurality of sample points and estimated density of each of the plurality of sample points;
an evaluation unit configured to calculate a difference amount between the teaching signal and the estimated signal; and
an updating unit configured to update the spatial estimation model, based on the difference amount.

In a second example aspect, a training method is to be executed by an arithmetic operation system, and includes:
acquiring, as a teaching signal, a spatial distribution signal observed by a sensor with respect to a spatial structure on a path of an emission wave by using the emission wave;
inputting information about a position of each of a plurality of sample points on the path to a spatial estimation model, and acquiring, from the spatial estimation model, estimated density related to a probability that an object emitting the emission wave from the plurality of sample points is present;
forming an estimated signal for comparing with the teaching signal, based on information about a position of each of the plurality of sample points and estimated density of each of the plurality of sample points;
calculating a difference amount between the teaching signal and the estimated signal; and
updating the spatial estimation model, based on the difference amount.

In a third example aspect, a training program causes an arithmetic operation system to execute processing including:
acquiring, as a teaching signal, a spatial distribution signal observed by a sensor with respect to a spatial structure on a path of an emission wave by using the emission wave;
inputting information about a position of each of a plurality of sample points on the path to a spatial estimation model, and acquiring, from the spatial estimation model, estimated density related to a probability that an object emitting the emission wave from the plurality of sample points is present;
forming an estimated signal for comparing with the teaching signal, based on information about a position of each of the plurality of sample points and estimated density of each of the plurality of sample points;
calculating a difference amount between the teaching signal and the estimated signal; and
updating the spatial estimation model, based on the difference amount.

### BRIEF DESCRIPTION OF DRAWINGS

The above and other aspects, features and advantages of the present disclosure will become more apparent from the following description of certain example embodiments when taken in conjunction with the accompanying drawings, in which:

FIG. 1 is a diagram for describing a related art;

FIG. 2 is a block diagram illustrating one example of a system according to a first example embodiment;

FIG. 3 is a flowchart illustrating one example of processing operation of an arithmetic operation system according to the first example embodiment;

FIG. 4 is a diagram for describing one example of the processing operation of the arithmetic operation system according to the first example embodiment;

FIG. 5 is a flowchart illustrating one example of processing operation of an arithmetic operation system according to a second example embodiment;

FIG. 6 is a block diagram illustrating one example of a system according to a third example embodiment;

FIG. 7 is a flowchart illustrating one example of processing operation of a second training unit according to the third example embodiment;

FIG. 8 is a flowchart illustrating one example of processing operation of a first training unit according to the third example embodiment;

FIG. 9 is a diagram for describing a spherical coordinate system;

FIG. 10 is a diagram for describing, by using the spherical coordinate system, a content of the related art described before the first example embodiment;

FIG. 11 is a diagram for describing, by using the spherical coordinate system, contents of the first example embodiment and the second example embodiment;

FIG. 12 is a block diagram illustrating one example of a system according to a fourth example embodiment;

FIG. 13 is a diagram for describing one example of processing operation of a training unit according to the fourth example embodiment;

FIG. 14 is a diagram for describing training of a sampling region;

FIG. 15 is a diagram illustrating one example of a system according to a modification example of the fourth example embodiment; and

FIG. 16 is a diagram illustrating a hardware configuration example of an arithmetic operation system.

### EXAMPLE EMBODIMENT

Hereinafter, example embodiments will be described with reference to the drawings. Note that, in the present disclosure, the drawings may be associated with one or more example embodiments. In addition, each element of the drawings may apply to one or more example embodiments. In addition, in the example embodiments, the same or equivalent elements are denoted by the same reference signs, and redundant description thereof will be omitted.

A plurality of example embodiments described below may be implemented independently, or may be implemented in combination as appropriate. The plurality of example embodiments have novel features that are different from each other. Therefore, the plurality of example embodiments contributes to solving different objects or problems from each other, and contributes to achieving different advantageous effects from each other.

### RELATED ART

First, a related art will be described. The individual example embodiments are based on the techniques. In other words, these techniques may be incorporated into individual example embodiments.

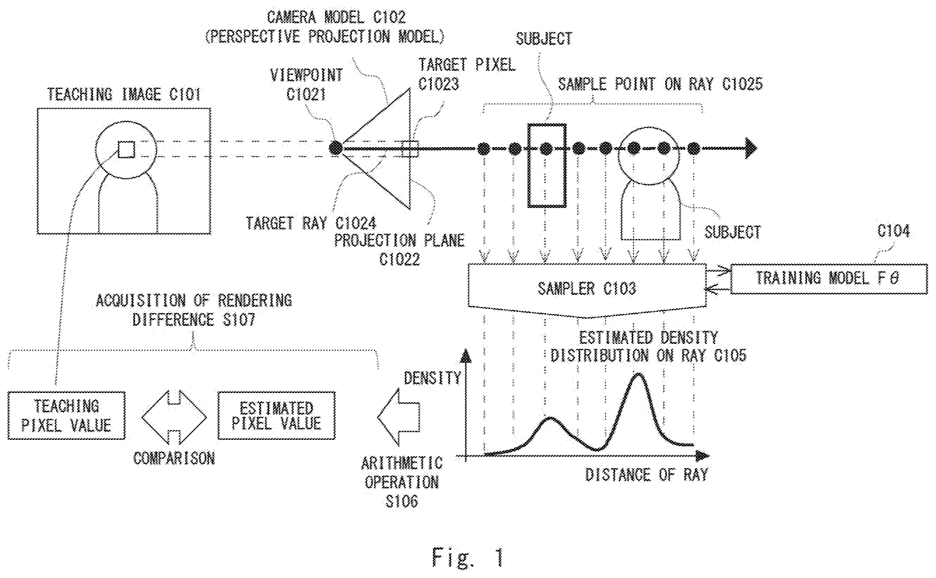

FIG. 1 is a diagram for describing the related art.

The related art is a framework in which training is advanced in such a way as to reduce a difference between a response result of a spatial estimation model (may be referred to as a “model to be trained” or simply as a “training model”. FIG. 1 illustrates as “Fθ”.) and an output of an actual camera.

A camera model of a teaching image C101 is considered as a perspective projection model C102. Herein, for a sake of understanding, first, a description will be given by paying attention to one pixel C1023 on a projection plane C1022 corresponding to a point C1021 being an installation position (viewpoint) of the camera model.

Each pixel position on the projection plane C1022 is equivalent to an angular direction (a horizontal direction, and a vertical direction) as viewed from the camera viewpoint C1021. That is, a luminance value of a certain pixel (herein, the pixel C1023) is determined by a physical action from all objects being present on the angular direction (a ray C1024) of a straight line connecting the camera viewpoint C1021 and a coordinate of the pixel C1023.

At a time of training a training model, an action on a pixel by an emission wave being emitted from a subject is estimated by performing some kind of physical simulation. Note that, by calculating a value of each pixel in the projection plane C1022 of the camera model by such a method, forming an image simulating an output of the actual camera is generally referred to as “rendering”. In the present disclosure, the interpretation is expanded, and a value (or distribution) equivalent to an output of an observation system is performed an arithmetic operation and output by physical simulation in a spatial model is referred to as “rendering” in a broad sense. The “rendering” in the broad sense is handled as similar to the “rendering” in a narrow sense.

As described above, when the viewpoint C1021 and the target pixel C1023 of the camera model C102 are determined, a ray C1024 being a target in a space can be defined.

Next, each of a plurality of points on the ray C1024 is set as a sampling point (sample point) C1025. Then, by inputting information about a position of each sample point to a training model C104, a value (for example, “density”) for each sample point is extracted from the training model C104. Herein, an operation of inputting information about the position of each sample point to the training model and acquiring a return value from the training model may be referred to as “sampling”. In addition, a functional unit that performs “sampling” may be referred to as a “sampler”. In addition, sampling may be performed by determining a “sampling region” and inputting a coordinate value of each sample point in the sampling region to the training model. Note that, information to be input to the training model C104 in a sampling process may include information such as a viewpoint angle in addition to the information about the position of each sample point. In addition, information to be output from the training model C104 in the sampling process may include information such as color in addition to the “density”. That is, in the training framework, the training model is regarded as a continuous function in which a coordinate, a viewpoint angle, and the like are input and information such as density and color is returned, and is interpreted as an approximation function of a distribution function expressing a space.

By collecting the outputs from the training model C104 based on the input of each sample point C1025, an estimated density distribution C105 on the ray C1024 is acquired. Since a difference amount (loss amount) from teaching data is required for training, rendering may be performed based on the density distribution in order to compare with the teaching data. Herein, in Non Patent Literatures 1 and 2, a “difference amount” is calculated by comparing a value (estimated pixel value) acquired by performing an arithmetic operation S106 including line integration on the estimated density distribution C105 with an output of a camera or a LiDAR (in FIG. 1, a pixel value corresponding to the target pixel C1023 in the teaching image C101). Although not illustrated in FIG. 1, a plurality of such cameras (as many as about 100 in Non Patent Literatures 1 and 2) are arranged in such a way as to surround a subject. For each of all combinations of all these viewpoints and all pixels, a ray can be defined, and the “difference amount” can be acquired for each combination similarly. In all of the rays, the training model trains a spatial structure by advancing training in such a way as to reduce a difference between the teaching data and a rendering result.

However, as described above, when the arithmetic operation S106 including line integration is performed on the estimated density distribution C105 in the rendering, as in Non Patent Literatures 1 and 2, information in a distance direction is compressed into information on one point (in other words, zero-dimensional information). Therefore, in Non Patent Literatures 1 and 2, abundant information distributed in an original distance direction cannot be effectively utilized. As a result, in the techniques disclosed in Non Patent Literatures 1 and 2, there is a possibility that spatial training is not efficiently performed.

Note that, arrangement (step, distribution) of the sampling point C1025 may be dynamically varied in such a way as to be sampled more in a region in which density is estimated to be higher over a course of training from a point of view of calculation efficiency.

In addition, similarly to Non Patent Literature 1, in order to train a structure having a higher resolution, a value acquired by projecting a coordinate value or an angle value into a high-dimensional vector referred to as “positional encoding (PE)” may be input to the training model Fθ, instead of inputting the coordinate value or the angle value as it is to the training model Fθ. That is, some transformation may be performed on the coordinate value or the angle value before inputting to the training model. Various methods of the PE have been proposed and has different effects from each other, and thereby it is preferable to select each of them depending on the application. Therefore, in the present disclosure, such a projective transformation is commonly referred to as the PE.

### First Example Embodiment

### Configuration Example of System

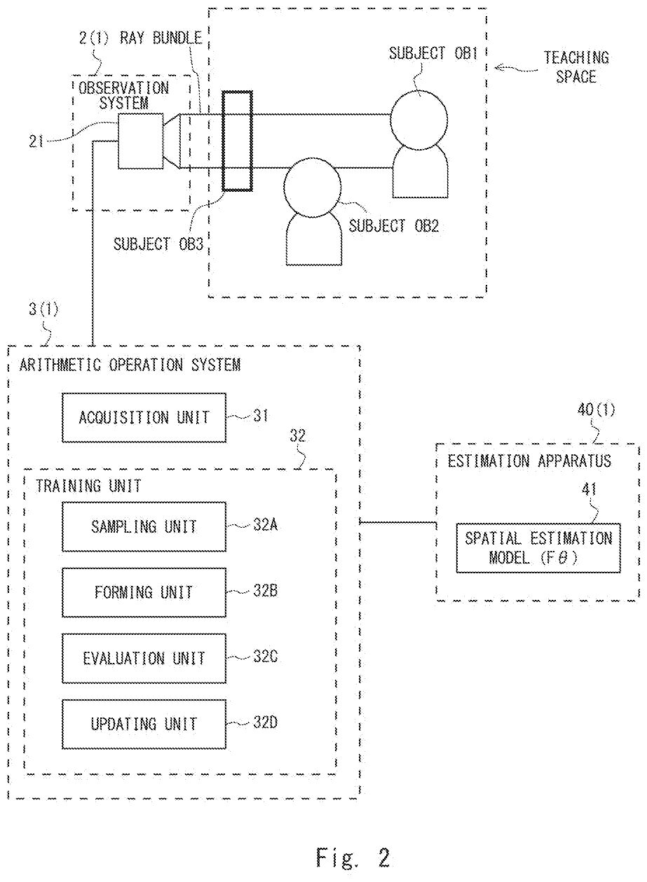

FIG. 2 is a block diagram illustrating one example of a system according to a first example embodiment. In FIG. 2, a system 1 includes an observation system 2, an arithmetic operation system 3, and an estimation apparatus 40. Note that, although one example of division of functions is illustrated in FIG. 2, a way of dividing the functions is not limited thereto. That is, functional units illustrated in FIG. 2 may be divided as appropriate, or may be aggregated in any combination. In addition, a way of distribution of each functional unit to the system or the apparatus in FIG. 2 is one example, and is not limited thereto. For example, the estimation apparatus 40 may be included in the arithmetic operation system 3. In addition, a plurality of functional units included in the arithmetic operation system 3 may be distributed to a plurality of independent apparatuses connected to each other.

### (Regarding Arithmetic Operation System and Estimation Apparatus)

In FIG. 2, the arithmetic operation system 3 includes an acquisition unit 31, and a training unit 32. The training unit 32 includes a sampling unit 32A, a forming unit 32B, an evaluation unit 32C, and an updating unit 32D. In FIG. 2, the estimation apparatus 40 stores a spatial estimation model 41. Note that, the sampling unit 32A and the forming unit 32B are equivalent to a functional unit that performs “rendering” described above. That is, the sampling unit 32A and the forming unit 32B are included in a “renderer”.

The acquisition unit 31 acquires a spatial distribution signal observed by using an emission wave with respect to a spatial structure on a path of the emission wave in a target space (i.e., a teaching space) by making a teaching signal. The “emission wave” and the “spatial distribution signal” will be described in detail later.

The sampling unit 32A inputs, to the spatial estimation model 41, information about a position of each of a plurality of sample points on the above-described path. With the input, the spatial estimation model 41 outputs estimated density related to a probability in which an object (i.e., a subject) emitting an emission wave is present on each sample point. Then, the sampling unit 32A acquires the estimated density output from the spatial estimation model 41. As a result, the sampling unit 32A can acquire a correspondence relationship between the information about a position of each of the plurality of sample points and estimated density associated to each sample point.

The forming unit 32B forms an estimated signal, based on the information about the position of each of the plurality of sample points and the estimated density of each of the plurality of sample points. The “estimated signal” is a signal for comparing with the teaching signal, and is a signal of a form similar to that of the teaching signal.

The evaluation unit 32C calculates a difference amount between the teaching signal and the estimated signal for each of a plurality of comparison points. The plurality of comparison points may be a same as the plurality of sample points described above.

The updating unit 32D updates the spatial estimation model, based on the difference amount. That is, the updating unit 32D updates the spatial estimation model in such a way that the difference amount becomes small. As a result, training of the spatial estimation model advances.

As described above, in the arithmetic operation system 3, the evaluation unit 32C calculates a difference amount between a teaching signal and an estimated signal. The teaching signal is a spatial distribution signal. In addition, the estimated signal is a signal for comparing with the teaching signal, and is an estimated spatial distribution signal. That is, since the evaluation unit 32C directly compares the teaching signal with the estimated signal, both in a form of the spatial distribution signal, it is possible to acquire a large number of difference amounts as compared with Non Patent Literatures 1 and 2 (i.e., a case where a difference between a pixel value of teaching data and an estimated pixel value is acquired). Since the updating unit 32D can update a spatial estimation model, based on the large number of difference amounts, the training can be performed more efficiently. In addition, since efficiency of the training leads to a reduction in a training cost, it is possible to reduce a calculation amount or a calculation time. In addition, a difference signal (amount of loss) acquired from one viewpoint of a sensor 21 increases. Therefore, the number of sensors 21 required in the system 1 or an angle of view (the number of rays to be defined) of the sensor 21 can be reduced as long as the amount of loss is the same, in Comparison with Non Patent Literatures 1 and 2.

### (Regarding Observation System)

In FIG. 2, the observation system 2 includes the sensor 21. The sensor 21 may be, for example, a LiDAR. Note that, although one sensor 21 is illustrated in FIG. 2, the observation system 2 includes a plurality of the sensors 21.

The sensor 21 observes a spatial structure on a path of an emission wave in a target space (i.e., a teaching space) by using the emission wave. By the observation, a spatial distribution signal is acquired. The “spatial distribution signal” is a signal indicating a spatial distribution of one or more dimensions. That is, the “spatial distribution signal” includes, for example, a signal representing intensity of the emission wave emitted at each point with respect to a distance from a reference point to each point on the path, the signal being acquired based on the emission wave acquired from the above-described path. The emission wave in a case where a LiDAR is selected as the sensor 21 is a reflected wave in which an electromagnetic wave irradiated to an emission wave path is reflected by an object and returns to the sensor 21 via the emission wave path.

In the teaching space illustrated in FIG. 2, subjects OB1, OB2, and OB3 are observed by a ray bundle (bundle of rays) irradiated from the sensor 21, and a spatial distribution signal is generated. As described above, the acquisition unit 31 acquires the spatial distribution signal as a teaching signal.

Herein, a commercially available LiDAR generally outputs only a value of one distance after being internally processed, that is, a signal equivalent to zero dimensions, and a one-dimensional signal of an intensity distribution with respect to a distance as described above is often an internal intermediate signal in the commercially available LiDAR. Therefore, when the commercially available LiDAR is used as the sensor 21, the one-dimensional intensity distribution signal is used as a teaching signal.

### Operation Example of System

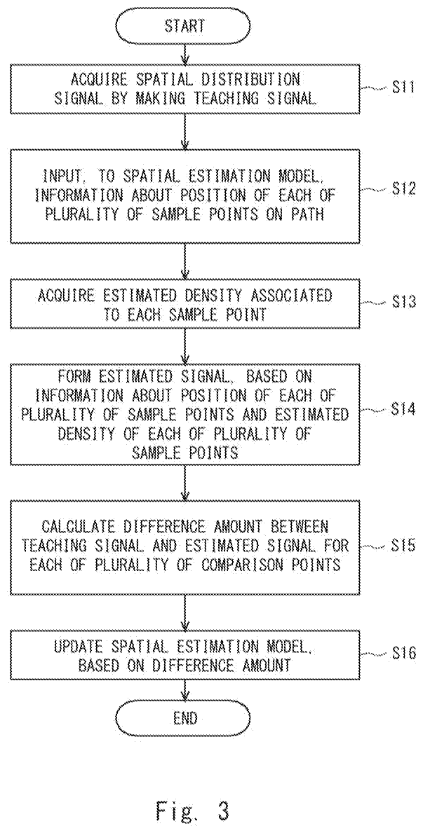

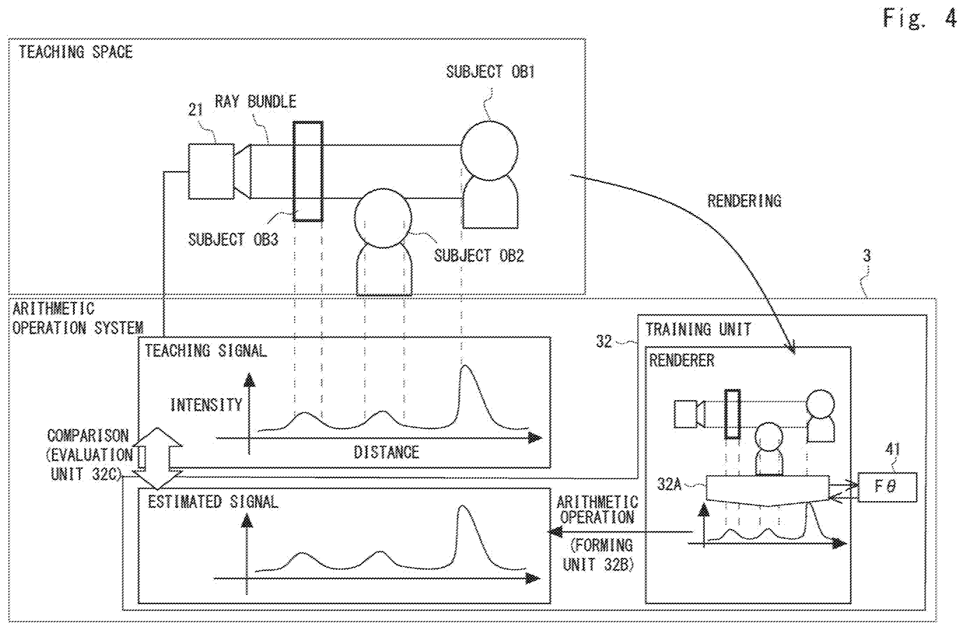

One example of processing operation of the system 1 having the above-described configuration will be described. Herein, processing operation of the arithmetic operation system 3 will be mainly described. FIG. 3 is a flowchart illustrating one example of the processing operation of the arithmetic operation system 3 according to the first example embodiment. FIG. 4 is a diagram for describing one example of the processing operation of the arithmetic operation system 3 according to the first example embodiment.

In the arithmetic operation system 3, the acquisition unit 31 acquires a spatial distribution signal observed by using an emission wave with respect to a spatial structure on a path of the emission wave by making a teaching signal (step S11).

The sampling unit 32A inputs information about a position of each of a plurality of sample points on the above-described path to the spatial estimation model 41 (step S12). With the input, the spatial estimation model 41 outputs estimated density related to a probability in which an object (i.e., a subject) emitting the emission wave is present on each sample point.

The sampling unit 32A acquires the estimated density being associated to each sample point and being output from the spatial estimation model 41 (step S13).

The forming unit 32B forms an estimated signal, based on the information about the position of each of the plurality of sample points and the estimated density of each of the plurality of sample points (step S14). The “estimated signal” is a signal for comparing with the teaching signal, and is a signal of a form similar to that of the teaching signal.

The evaluation unit 32C calculates a difference amount between the teaching signal and the estimated signal for each of a plurality of comparison points (step S15). The plurality of comparison points may be a same as the plurality of sample points described above.

The updating unit 32D updates the spatial estimation model, based on the difference amount (step S16). That is, the updating unit 32D updates the spatial estimation model in such a way that the difference amount becomes small. As a result, training of the spatial estimation model advances.

As described above, according to the first example embodiment, in the arithmetic operation system 3, the acquisition unit 31 acquires a spatial distribution signal observed by using an emission wave with respect to a spatial structure on a path of the emission wave by making a teaching signal. The sampling unit 32A inputs information about a position of each of a plurality of sample points on the above-described path to the spatial estimation model 41. The sampling unit 32A acquires estimated density output from the spatial estimation model 41. The forming unit 32B forms an estimated signal, based on the information about the position of each of the plurality of sample points and the estimated density of each of the plurality of sample points. The evaluation unit 32C calculates a difference amount between the teaching signal and the estimated signal. The teaching signal is a spatial distribution signal. In addition, the estimated signal is a signal for comparing with the teaching signal, and is an estimated spatial distribution signal. The updating unit 32D updates the spatial estimation model, based on the difference amount.

According to the configuration of the arithmetic operation system 3, since the teaching signal and the estimated signal, both in a form of the spatial distribution signal, are directly compared with each other, it is possible to acquire a large number of difference amounts as compared with Non Patent Literatures 1 and 2 (i.e., a case where a difference between a pixel value of teaching data and an estimated pixel value is acquired). Since the updating unit 32D can update the spatial estimation model, based on the large number of difference amounts, the training can be performed more efficiently. In addition, since efficiency of the training leads to a reduction in a training cost, it is possible to reduce a calculation amount or a calculation time. In addition, a difference signal (amount of loss) acquired from one viewpoint of the sensor 21 increases. Therefore, the number of sensors 21 required in the system 1 or an angle of view (the number of rays to be defined) of the sensor 21 can be reduced as long as the amount of loss is the same, in comparison with Non Patent Literatures 1 and 2.

### Second Example Embodiment

In particular, a second example embodiment relates to a specific example of a configuration and a specific example of operation of the observation system, the arithmetic operation system, and the spatial estimation model described in the first example embodiment.

### Configuration Example of System

A basic configuration of a system of the second example embodiment is the same as that of the system 1 of the first example embodiment, and therefore will be described with reference to FIG. 2.

### (Regarding Observation System)

A plurality of sensors 21 constituting an observation system 2 may be a LiDAR as described above. Many LiDARs adopt a time of flight (ToF) scheme that measures a distance by using a time difference of a reflected pulse from a subject with respect to a transmitted optical pulse. The sensor 21 may be such a LiDAR. As described above, the sensor 21 can acquire a distribution signal of one or more dimensions from a space. The distribution signal of one or more dimensions is, as described above, a distribution of an intensity signal with respect to a distance.

Note that, although not illustrated in FIG. 2, the observation system 2 includes a plurality of sensors 21, and a plurality of sensors 21 are disposed around a subject. The observation system 2 can acquire information from a plurality of viewpoints. It is preferable that at least three or more of the sensors 21 of the observation system 2 are arranged in such a way as to surround a subject, although depending on required shape accuracy. That is, it is preferable that the observation system 2 can acquire information from three or more viewpoints. Further, when information from six or more viewpoints can be acquired, the observation system 2 can acquire a higher definition image. Furthermore, when information from ten or more viewpoints can be acquired, the observation system 2 can also have redundancy, and is more useful. In addition, in a case where a purpose is satisfied by acquiring shape information on one side of a subject (i.e., in a case where a shape on a back side is unnecessary), the sensor 21 of the observation system 2 may be concentrated and arranged on one side of the subject. In addition, the sensor 21 forming one viewpoint of the observation system 2 may be formed from a plurality of measuring instruments. That is, a sensor having a sensor array including a plurality of measuring instruments can be used as the sensor 21.

Herein, a type of the sensor 21 included in the observation system 2 will be described. In the principle of the technique of the present disclosure, even comparison of signals each of which is a signal of one or more dimensions can be trained similarly. For this reason, a LiDAR with a method of transmitting a modulated optical signal and acquiring a distance from a phase difference between a reflected optical signal and the transmitted optical signal may be adopted as the sensor 21. From a broader point of view, it is only necessary to configure an observation system in which a teaching signal that can be compared with an estimated signal acquired by performing sampling from a training model and an arithmetic operation is acquired. Therefore, the sensor 21 of the observation system 2 is not limited to a LiDAR, and the type of the sensor is not limited. For example, a sensor using a medium, such as an electric wave or a sound wave, spreading in a wavefront shape for sensing may be adopted as the sensor 21. The extension example will be described in a fourth example embodiment.

When the sensor 21 is a LiDAR, a sensor medium (emission wave) is a ray bundle. The ray bundle at a time of irradiation is irradiated from a “reference point (i.e., a position of the sensor 21)” toward each “emission reference direction”. The larger the ray bundle diameter, the more objects that interfere with the ray bundle in an observation region of the sensor 21 (i.e., a region in the ray bundle) increase (for example, a subject OB2). Therefore, information acquired by reflection of one ray bundle irradiated to each “emission reference direction” also increases. However, as a result, resolution per angle (i.e., per one emission reference direction) of the single sensor 21 decreases. As a result, it becomes difficult to detect a small object. This is synonymous with acquiring a blurred image in a photograph. This problem can be improved by, for example, a scanning method and a training method of a LiDAR. With respect to the scanning method, it is effective to make a step of an angular direction of the sensor 21 for receiving a reflected signal smaller than a ray bundle diameter (a diameter of an effective region of an emission wave). For example, the sensor 21 may be changed little by little the angular direction for receiving the reflected signal while having a region that overlaps with each other. Thus, the sensor 21 can acquire information having high resolution. Thus, spatial resolution can be improved. Note that, at this time, a plurality of sample points handled by a sampling unit 32A includes, in addition to a plurality of “main sample points” on a straight line extending from a reference point to an emission reference direction, a plurality of “sub sample points” being in an emission wave region extending in a direction orthogonal to the straight line and deviating from the straight line.

In addition, when the number of sensors 21 (i.e., the number of viewpoints) can be increased and a ray from a larger number of angular directions with respect to a region having a subject can be defined, spatial resolution after training can be improved. For example, when each of the plurality of sensors 21 is a LiDAR having a ray bundle diameter of 20 mm, the plurality of sensors 21 can reconstruct an image of an object having a size of about 10 mm being smaller than the ray bundle diameter by an action of signals from a plurality of viewpoints. Note that, in the description herein, since the sensor 21 is assumed to be a LiDAR, the sensor medium is light (a ray bundle). However, a type of the sensor medium is not limited as long as spatial information is acquired as a distribution signal. In the present disclosure, a signal received along a path extending radially from a sensor can be handled as a teaching signal. For this reason, in the present disclosure, a sensor medium on which a signal due to an action of the space is carried is referred to as an “emission wave” for convenience. In addition, in the present disclosure, “emission” includes “reflection”, “radiation”, “fluorescence”, and the like.

In addition, a transmission unit of a signal forming an emission wave and a reception unit that receives a reflected wave may be separated and arranged at different positions from each other. In this case, it is assumed that an irradiation region at a time of transmission does not overlap with an emission wave region at a time of reception, but when the arrangement of the transmission unit and the arrangement of the reception unit are known, a signal received by the reception unit can be modeled. In addition, a medium of an irradiation wave at the time of transmission for generating an emission wave to be received may not be the same as a medium of the emission wave to be received. For example, as in a case of an “optical ultrasonic technique”, a system in which a sound wave signal is acquired, as an emission wave, from a subject by applying an action to the subject by using light as an input may be adopted. In other words, the irradiation wave in the present disclosure is interpreted as a medium that provides an action for generating a desired emission wave from a subject. Therefore, a portion described as a “reflected wave” hereinafter is similar to the “emission wave generated by the action of the irradiation wave”.

### (Regarding Arithmetic Operation System and Spatial Estimation Model)

In order to acquire an estimated signal, a training unit 32 successively performs determination of an observation region, sampling, input/output to/from a training model, and various arithmetic operations such as a physical operation. These pieces of processing are concatenated in a framework of “differentiable rendering”, and a calculation graph is formed and maintained. When “loss” can be acquired by comparing a teaching signal with an estimated signal, an action of back propagation of an error will lead to optimization of all trainable parameters on the calculation graph. As a result, training advances. In order to achieve such differentiable rendering, arithmetic expressions may be combined by using Tensorflow, Pytorch, or the like being a typical DeepLearning framework. As a result, a user is not conscious, the calculation graph can be constructed, and the back propagation of the error functions. Herein, although a parameter that can be optimized is assumed to be θ in a spatial estimation model 41 in the present disclosure, another parameter may be added to a variable. For example, a sensor position, a sensor angle, or the like may be set as a variable. A s a result, the training can be advanced in such a way that an error of an input value is also corrected. In the present disclosure, for example, a mathematical expression for determining a path and an observation region of a ray may be defined by a parameter, and the parameter may be added to a training parameter. As a result, it is possible to train (estimate) a fluctuation of an emission wave. For example, in a course of training, when a ray bundle (ray) is optimized non-linearly, this can also be interpreted as capturing a refractive index distribution in a space.

The spatial estimation model 41 is a training-type function Fθ expressing a spatial distribution. Also in Non Patent Literature 1, the training model is represented by “Fθ”, and when information about a position of a certain point such as a coordinate or an observation angle is input, density, color information, and the like of the point are returned. Input/output of the training model is regarded as a kind of “distribution function” that can respond to a continuous value.

θ indicates an internal parameter of the spatial estimation model 41. By optimizing θ, a function capable of expressing a spatial distribution is gradually formed. The spatial estimation model 41 is represented by a symbol “Fθ” in FIGS. 1 and 2. In the present disclosure, the training model Fθ may be multi layer perceptron (MLP) similar to that of Non Patent Literature 1. Since it is possible to approximate expression of various functions (shapes) with a simple structure and a small amount of data, MLP is often used as a training model. However, in recent years, it has been found that the training model is not limited to a neural net, and that the training model of octree expression or voxel expression can train similar to NeRF. Therefore, also in the present disclosure, a form of the training model Fθ and the type thereof are not limited. A distribution function having a training parameter (θ) and returning density (a distribution) when a parameter such as a coordinate and an angle are input can be used as a training model of the present disclosure. In addition, as described above, projective transformation PE may be executed at a time of input to the training model.

In addition, an input parameter to the function Fθ adopted in the spatial estimation model 41 may include information other than position information. For example, Non Patent Literature 1 introduces a physical model in which a reflection color of an appearance of an object varies depending on a viewing angle. For example, in Non Patent Literature 1, direction information and the like of a sample point coordinate with respect to the sensor 21 is input to the training model Fθ. As described in Non Patent Literature 1, the training model Fθ may be internally divided into a plurality of functional units. For example, the training model Fθ may include a functional unit that performs spatial density calculation, a functional unit that calculates a difference in appearance depending on a viewing angle, a functional unit that manages a time change, a functional unit that separates individual objects, and the like. When each of these functional units requires different information from each other, such information may also be added to the input parameter.

A renderer (i.e., the sampling unit 32A and a forming unit 32B) functions as a kind of a sensor simulator. That is, the renderer (i.e., the sampling unit 32A and the forming unit 32B) performs rendering according to a physical model of the sensor 21, and generates an estimated signal (estimated distribution) for comparing with a teaching signal. The sampling unit 32A of the renderer performs determining a spatial region (i.e., an emission wave region and an estimated observation region) in which a virtual sensor signal on the simulation receives an action, and inputting and outputting to and from the training model Fθ. In addition, the forming unit 32B of the renderer reproduces an estimated signal from an output (estimated density distribution) from the spatial estimation model 41. The output of the spatial estimation model 41 is density (herein, a plurality of pieces of density is equivalent to a “density distribution”). The forming unit 32B may convert the density distribution sampled by the sampling unit 32A into a “weight value” equivalent to intensity observed by the sensor 21 by spatial propagation calculation in which transmittance on a path is taken into consideration. In this way, an estimated intensity distribution (i.e., an estimated signal) for a distance in a ray axis is acquired.

The sampling unit 32A determines information to be input to the spatial estimation model 41 by determining a “spatial region (an emission wave region, an estimated observation region)” and the like acting on a reception signal of the (virtual) sensor 21. For example, a spatial region (a coordinate of a sample point) being considered to act on a reception signal of the sensor 21 is determined from information such as a viewpoint position and a ray direction of each sensor 21 (LiDAR) arranged in a teaching space, and a thickness of the ray. As described above, when a relatively large ray bundle diameter is used, the coordinate of the sample point is sampled in consideration of an effective region of the diameter of the emission wave.

In addition, in Non Patent Literatures 1 and 2, the spatial region (emission wave region, estimated observation region) is a straight line extending in a ray direction. However, in the present disclosure, the spatial region (emission wave region, estimated observation region) is not limited to the straight line. For example, when the sensor 21 is a LiDAR, as illustrated in the teaching space in FIG. 2, the ray bundle has a ray bundle width (diameter) being a finite width. In this example, not only a subject OB1 being a main subject, but also the subject OB2 being deviated from an optical axis of the ray is observed. In addition, the same applies to a transparent body (subject OB3) having a refractive index at a wavelength of a LiDAR ray, and a value of reflection of the portion is similarly observed as a reception signal. In particular, since a LiDAR is a sensor capable of distance resolution, several peaks (intensity) are acquired for a distance with respect to intensity of the reception signal. In the present disclosure, the intensity of the reflected light reflected by each object interfering with the ray bundle can be used as a teaching signal. Therefore, in order to reproduce the width of the ray bundle being the sensor medium, the sampling unit 32A samples not only a point at a center of the optical axis but also a region away from the optical axis, so that rendering accuracy can be further increased. That is, as described above, a plurality of sample points handled by the sampling unit 32A may include, in addition to a plurality of “main sample points” on a straight line (i.e., an optical axis) extending from a reference point to an emission reference direction, a plurality of “sub sample points” being in an emission wave region extending in a direction orthogonal to the straight line and deviating from the straight line. As a method of sampling in a ray bundle width direction, for example, a method of simply casting a ray in a plurality of directions having a small angle difference from each other and increasing the number of sample points can be considered. However, in principle, since it is only necessary to acquire an integrated value of a substantial space, a mathematically equivalent arithmetic operation can also be used. For example, a method in which a coordinate vector after performing PE is integrated first may be used.

In addition, as described above, a parameter input to the spatial estimation model 41 may include a parameter other than the position information. In this case, the sampling unit 32A appropriately selects a parameter other than the position information as well, and inputs the selected parameter to the spatial estimation model 41.

In addition, as described above, when information is input to the spatial estimation model 41, any conversion such as the PE may be performed.

By the above-described method, the sampling unit 32A determines information of a sampling point to be input to the spatial estimation model 41.

The forming unit 32B may include a distribution calculation unit (not illustrated) that configures an estimated density distribution, based on an output from the spatial estimation model 41, and a conversion unit (not illustrated) that converts the estimated density distribution into an estimated signal, based on a physical operation.

An evaluation unit 32C acquires a “loss amount (i.e., difference amount)” by comparing a teaching signal and an estimated signal.

When the loss amount is acquired, as described above, training (optimization) for various parameters advances under the principle of differentiable rendering. The loss amount is acquired separately for a signal of each direction acquired by each sensor 21 included in the observation system 2. For this reason, in such a way that all the loss amounts become small, an updating unit 32D repeatedly updates the parameter of the spatial estimation model 41, and advances the training of the spatial estimation model 41. As a result, the trained spatial estimation model 41 can form a spatial distribution in which a spatial distribution of the teaching region is reproduced with high accuracy.

### Operation Example of System

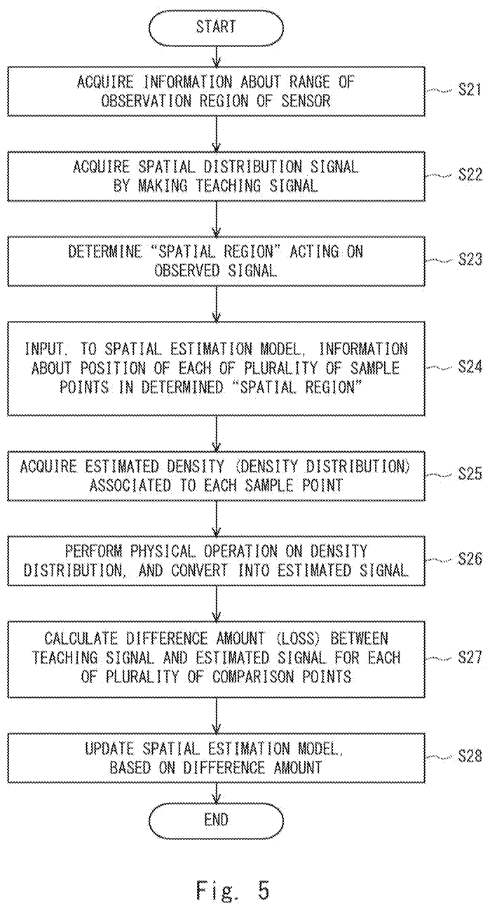

One example of processing operation of the system 1 having the above-described configuration will be described. Herein, processing operation of an arithmetic operation system 3 will be mainly described. FIG. 5 is a flowchart illustrating one example of the processing operation of the arithmetic operation system 3 according to the second example embodiment.

In the arithmetic operation system 3 according to the second example embodiment, an acquisition unit 31 acquires information about a range of an observation region (i.e., a region to which an emission wave extends) acting on an observed signal of the sensor 21 (LiDAR) (step S21). The acquisition unit 31 may acquire information about a viewpoint and a direction of the sensor 21, and determine information about the range of the observation region, based on the acquired information.

The acquisition unit 31 acquires a spatial distribution signal observed by using an emission wave with respect to a spatial structure on a path of the emission wave by making a teaching signal (step S22).

The sampling unit 32A determines a “spatial region (estimated observation region, emission wave region)” acting on the observed signal (step S23).

The sampling unit 32A inputs information about a position of each of a plurality of sample points in the determined “spatial region” to the spatial estimation model 41 (step S24). With the input, the spatial estimation model 41 outputs estimated density (i.e., a density distribution) related to a probability in which an object (i.e., a subject) emitting an emission wave is present on each sample point.

The sampling unit 32A acquires the estimated density (i.e., the density distribution) being associated to each sample point and being output from the spatial estimation model 41 (step S25).

The forming unit 32B performs a physical operation on the density distribution, and converts the performed density distribution into an estimated signal (step S26). The “estimated signal” is a signal for comparing with the teaching signal, and is a signal of a form similar to that of the teaching signal.

The evaluation unit 32C calculates a difference amount (loss) between the teaching signal and the estimated signal for each of a plurality of comparison points (step S27). The plurality of comparison points may be a same as the plurality of sample points described above.

The updating unit 32D updates the spatial estimation model, based on the difference amount (loss) (step S28). That is, the updating unit 32D updates the spatial estimation model in such a way that the difference amount (loss) becomes small. As a result, training of the spatial estimation model advances. Note that, herein, for simplicity of description, a flow has been described focusing on one sensor 21, but a similar arithmetic operation is performed for each angle of view direction of each sensor 21, and the training is advanced.

Note that, in step S23, it is preferable that an interval between two adjacent sample points, a distribution of the sample points, and the like are set according to a step of the teaching signal acquired by the sensor 21, since it is easy to acquire the difference amount in subsequent step S27. It should be understood that data structure does not necessarily have to be matched at a sampling stage, and may be aligned at a time of comparison of the distribution signals (S27). For example, a method of aligning the data structure at a time of outputting the conversion step (S26) may be used.

In addition to spatial propagation calculation, a simulation associated to a characteristic inside the sensor may be added to the arithmetic operation in step S26 in order to approach behavior of the actual sensor. For example, the estimated signal can be brought closer to the teaching signal by introducing conversion processing or the like of handling noise generated within the sensor, aliasing by a sampling period, or the like. As a result, training performance can be improved.

In steps S27 and S28, a function of a DeepLearning framework may be utilized to feedback a difference between the teaching signal and the estimated intensity distribution (estimated signal) to the training model. By performing calculation of the renderer (i.e., the sampling unit 32A and the forming unit 32B) using the DeepLearning framework, all of connections (calculation graphs) of the calculation performed in the renderer are maintained. Based on the difference between the teaching signal and the estimated intensity distribution (estimated signal), a differential amount is propagated to the parameter θ of the training model Fθ by an action of back propagation of an error. Based on the differential amount, training is advanced. The operation is referred to in various ways, such as “optimization”, “loss minimization”, and “minimization of an evaluation function”, but they can be mathematically considered as a similar operation. In the present disclosure, the operation may be simply referred to as “training.” In addition, there are various loss functions and optimization algorithms (optimizers) used for training. In the present disclosure, the type of loss function or optimization algorithm (optimizer) is not particularly limited. For example, a mean square error (MSE) between the teaching signal and the estimated signal may be used for the loss function. Since a one-dimensional signal being intensity data for each distance is used at a time of comparing the teaching signal and the estimated signal with each other, the MSE for each sample point may be adopted as the loss function of the evaluation unit 32C in the present example embodiment. In addition, a standard Adam may be used as the optimization algorithm.

### Third Example Embodiment

A third example embodiment relates to an example embodiment in which training of a spatial estimation model is performed based on signals observed by a plurality of sensors of different types.

### Configuration Example of System

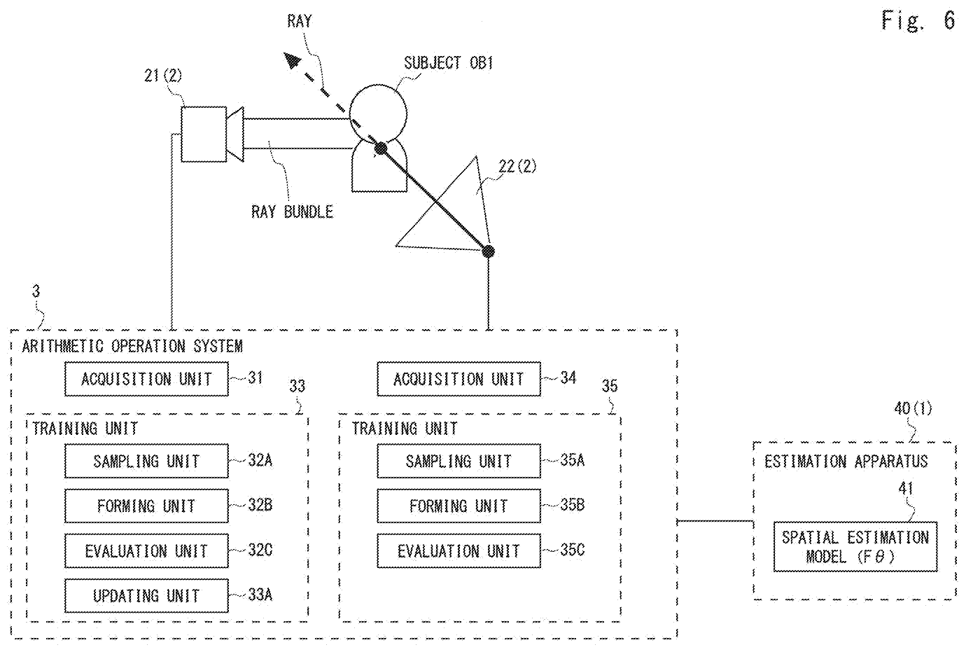

FIG. 6 is a block diagram illustrating one example of a system according to the third example embodiment. In FIG. 6, similarly to the first example embodiment, a system 1 includes an observation system 2, an arithmetic operation system 3, and an estimation apparatus 40. Note that, although one example of division of functions is illustrated in FIG. 6, a way of dividing the functions is not limited thereto. That is, functional units illustrated in FIG. 6 may be divided as appropriate, or may be aggregated in any combination. In addition, a way of distribution of each functional unit to the system or the apparatus in FIG. 6 is one example, and is not limited thereto. For example, the estimation apparatus 40 may be included in the arithmetic operation system 3. In addition, a plurality of functional units included in the arithmetic operation system 3 may be distributed to a plurality of independent apparatuses connected to each other.

### (Regarding Observation System)

In FIG. 6, the observation system 2 includes a sensor 22, in addition to a sensor 21. The sensor 22 is different in type from the sensor 21, and is disposed at a position different in a viewpoint from the sensor 21. As described in the first example embodiment, the sensor 21 observes a spatial structure on a path of an emission wave in a target space (i.e., a teaching space) by using the emission wave. By the observation, a spatial distribution signal is acquired.

The sensor 22 observes a “spatial characteristic parameter” other than the spatial structure in the target space (i.e., the teaching space), and acquires a “observed signal”. That is, herein, the “observed signal” is different in characteristic from the above-described spatial distribution signal. The “spatial characteristic parameter” means a parameter representing a characteristic of a space (object).

Hereinafter, it is assumed that the sensor 21 is a LiDAR and the sensor 22 is a two-dimensional RGB camera. In this case, in the sensor 21, a “spatial distribution signal” indicating a spatial distribution of one or more dimensions is acquired. In addition, in the sensor 22, a value related to color is acquired. That is, in this case, the above-described “spatial characteristic parameter” is “color (in a broader sense, a reflection spectrum)”. The observed signal of the sensor 22 (i.e., the value related to the color) is a luminance value, i.e., “zero-dimensional signal (information)”. Since the RGB camera can acquire a luminance value for each RGB, the observed signal of the sensor 22 is more precisely “three zero-dimensional signals”, but, in the description of the present example embodiment, is handled as a “zero-dimensional signal” in order to discuss about an order of a data amount.

Although one sensor 21 and one sensor 22 are illustrated in FIG. 6, the number is not limited thereto. In addition, although two types of sensors are illustrated in FIG. 6, the number of types of sensors is also not limited thereto. As described above, since accuracy of a spatial distribution function of a training model increases as the number of viewpoints increases, it is preferable that the number of sensors constituting the observation system 2 is larger. In particular, it is more desirable for the observation system 2 to include two or more types and four or more of sensors. This is because the larger the number of viewpoints, the higher the definition of an image reproduced by the training model, similarly to the first example embodiment.

### (Regarding Arithmetic Operation System)

In FIG. 6, the arithmetic operation system 3 includes an acquisition unit 31, a training unit (first training unit) 33, an acquisition unit 34, and a training unit (second training unit) 35. The training unit 33 includes a sampling unit 32A, a forming unit 32B, an evaluation unit 32C, and an updating unit 33A. The training unit 35 includes a sampling unit 35A, a forming unit 35B, and an evaluation unit 35C. Note that, the sampling unit 32A and the forming unit 32B are equivalent to a functional unit that performs “rendering” described above. That is, the sampling unit 32A and the forming unit 32B are included in a “first renderer”. In addition, the sampling unit 35A and the forming unit 35B are equivalent to a functional unit that performs “rendering” described above. That is, the sampling unit 35A and the forming unit 35B are included in a “second renderer”. Note that, herein, since the type of the sensor 21 and the type of the sensor 22 are different from each other, the first renderer and the second renderer are provided, but when the type of the sensor 21 and the type of the sensor 22 are the same, one renderer may be shared.

The sampling unit 32A, the forming unit 32B, and the evaluation unit 32C have been described in the first and second example embodiments, and thus description thereof will be omitted herein.

The acquisition unit 34 acquires an observed signal observed by the sensor 22 as a teaching signal (hereinafter, sometimes referred to as a “second teaching signal”). Note that, in the following description, a teaching signal acquired by the acquisition unit 31 may be referred to as a “first teaching signal”.

The sampling unit 35A inputs, to a spatial estimation model 41, information about a position of a sample point (hereinafter, sometimes referred to as a “second type sample point”) corresponding to an observation point observed by the sensor 22 in order to acquire the above-described observed signal. With the input, the spatial estimation model 41 outputs a parameter value (herein, a value related to color) related to a spatial characteristic parameter of the second type sample point. Then, the sampling unit 35A acquires the parameter value (herein, a value related to color) related to the spatial characteristic parameter of the second type sample point. Thus, it is possible to acquire a correspondence relationship between the information about the position of the second type sample point and the parameter value related to the spatial characteristic parameter of the second type sample point. Note that, in the following description, a sample point handled by the sampling unit 32A may be referred to as a “first type sample point”.

The forming unit 35B forms an estimated signal (hereinafter, sometimes referred to as a “second estimated signal”), based on the information about the position of the second type sample point and the parameter value related to the spatial characteristic parameter of the second type sample point. The “second estimated signal” is a signal for comparing with the second teaching signal, and is a signal of a form similar to that of the second teaching signal. Note that, in the following description, an estimated signal acquired by the forming unit 32B may be referred to as a “first estimated signal”.

The evaluation unit 35C calculates a difference amount (hereinafter, sometimes referred to as a “second difference amount”) between the second teaching signal and the second estimated signal. Note that, in the following description, a difference amount acquired by the evaluation unit 32C may be referred to as a “first difference amount”.

The updating unit 33A updates the spatial estimation model 41, based on the first difference amount and the second difference amount. For example, when the number of dimensions of the first estimated signal and the number of dimensions of the second estimated signal are different from each other (i.e., when the number of dimensions of the first teaching signal and the number of dimensions of the second teaching signal are different from each other), the updating unit 33A may perform weighting on the first difference amount and the second difference amount, and update the spatial estimation model 41, based on a sum value acquired by summing up the weighted first difference amount and the weighted second difference amount.

In addition, updating of a model by the first difference amount and updating of a model by the second difference amount are not necessarily performed at a same time, and may be performed at different timing from each other or may be performed alternately. In that case, it is not necessary to sum up each of the difference amounts, and only the weighting is performed. When a frequency of updating by each difference amount is different from each other, an update ratio thereof may be reflected in each weight.

As described above, in the third example embodiment, the training unit 33 and the training unit 35 advance training of the common spatial estimation model 41.

### Operation Example of System

One example of processing operation of the system 1 having the above-described configuration will be described. Herein, processing operation of the arithmetic operation system 3 will be mainly described.

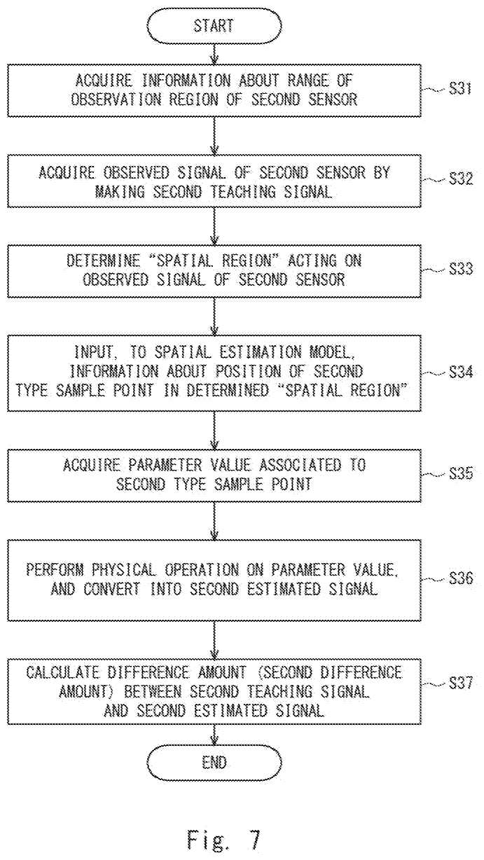

FIG. 7 is a flowchart illustrating one example of processing operation of the second training unit (training unit 35) according to the third example embodiment.

In the arithmetic operation system 3 according to the third example embodiment, the acquisition unit 34 acquires information about a range of an observation region acting on an observed signal of the sensor 22 (two-dimensional RGB camera) (step S31). The acquisition unit 34 may acquire information about a viewpoint and a direction of the sensor 22, and determine information about the range of the observation region, based on the acquired information.

The acquisition unit 34 acquires the observed signal observed by the sensor 22 as a second teaching signal (step S32).

The sampling unit 35A determines a “spatial region (estimated observation region, emission wave region)” acting on the observed signal of the sensor 22 (step S33).

The sampling unit 35A inputs information about a position of a second type sample point in the determined “spatial region” to the spatial estimation model 41 (step S34). With the input, the spatial estimation model 41 outputs a parameter value (herein, a value related to color) related to a spatial characteristic parameter of the second type sample point.

The sampling unit 35A acquires the parameter value (herein, a value related to color) related to the spatial characteristic parameter of the second type sample point (step S35).

The forming unit 35B performs a physical operation on the parameter value (herein, a value related to color), and converts the performed parameter value into a second estimated signal (step S36). The second estimated signal is a signal for comparing with the second teaching signal, and is a signal of a form similar to that of the second teaching signal.

The evaluation unit 35C calculates a second difference amount being a difference amount between the second teaching signal and the second estimated signal (step S37). The second difference amount is used by the updating unit 33A.

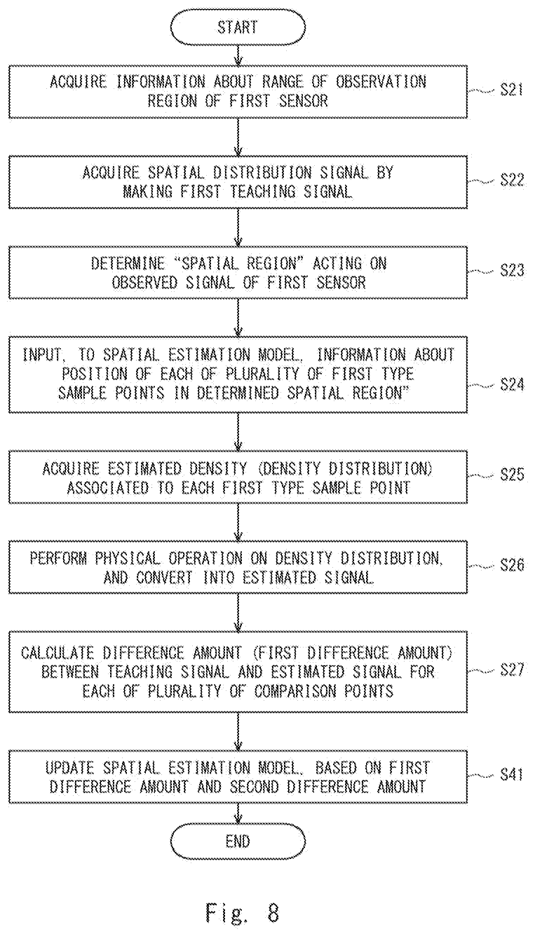

FIG. 8 is a flowchart illustrating one example of processing operation of the first training unit (training unit 33) according to the third example embodiment. Steps S21 to S27 have been described in the second example embodiment, and thus description thereof will be omitted.

The updating unit 33A updates the spatial estimation model 41, based on a first difference amount and a second difference amount (step S41).

Herein, in the above example, the number of dimensions of the first difference amount and the number of dimensions of the second difference amount are different from each other. That is, an observed signal acquired by the sensor 21 is a density distribution signal of one dimension, and an observed signal acquired by the sensor 22 is a zero-dimensional signal. It is assumed that, for example, a step of a distance axis with respect to the observed signal acquired by the sensor 21 is 100. At this time, influence of the observed signal acquired by the sensor 21 on the first difference amount (loss) may be 100 times influence of the observed signal acquired by the sensor 22 on the second difference amount (loss) (in a case of the same numerical type). Therefore, in order to eliminate imbalance of an action on the training model due to a difference in the dimension of the estimated signal, the updating unit 33A may perform an arithmetic operation of reducing a dimension difference.

The arithmetic operation for relaxing the dimensional difference may be performed on the first difference amount, may be performed on the second difference amount, or may be performed on both of the first difference amount and the second difference amount. The simplest method is a linear method in which coefficients are multiplied for each difference amount (loss). For example, when the one-dimensional signal of the sensor 21 is N steps, the updating unit 33A may multiply the first difference amount by a coefficient 1/N. As a result, the first difference amount and the second difference amount are leveled. Conversely, the updating unit 33A may multiply the second difference amount by a coefficient N.

In addition, for example, when information on the sensor 22 is more important than information on the sensor 21, the updating unit 33A may adjust a weighting coefficient to be multiplied by the second difference amount in such a way that a value of the second difference amount becomes larger.

As described above, according to the third example embodiment, since a training model is trained by using a plurality of types of sensors, it is possible to more efficiently advance training of the spatial estimation model by using different pieces of information acquired by each of the sensors. In addition, the spatial estimation model can simultaneously train different attributes acquired by each of the sensors.

### Modification Example

<1> In the above description, a case where the sensor 22 is a two-dimensional RGB camera has been described as an example, but the present disclosure is not limited thereto. For example, the sensor 22 may be a sensor capable of observing an object reflectance (BRDF in a broader sense) as a spatial characteristic parameter, or may be a sensor capable of observing a heat distribution as a spatial characteristic parameter. In addition, the sensor 22 may be a sensor capable of observing roughness, texture, material, a component, or the like of a surface as a spatial characteristic parameter.

In addition, the sensor 22 may be an acoustic sensor capable of observing sound volume, surface elasticity, or the like of a sound source as a spatial characteristic parameter.

By mixing a wide variety of sensors in the observation system 2, an object characteristic that cannot be acquired by a single sensor can be given to the same distribution function (i.e., training model). An imaging method for integrating such a plurality of types of sensors is referred to as sensor fusion, multi-modal sensing, or the like.
<2> The sensor (in particular, the sensor 22) of the third example embodiment may not be an active sensor provided with a transmitter (irradiation unit), and may be a sensor that acquires a spatial signal from a medium signal in a space. For example, cameras that measure depth geometrically and optically with a principle of a camera such as a stereo camera and a light field camera can be regarded as sensors that can measure a distance by observing and analyzing a reflected ray from an object due to environmental illumination. An output of such a sensor is a depth image such as a LiDAR. Therefore, such a sensor may be used as the sensor of the third example embodiment.

### Fourth Example Embodiment

A fourth example embodiment relates to training of a spatial estimation model using, as a teaching signal, a spatial distribution signal observed for a spatial structure along a region of interest being a curved line region or a curved surface region intersecting a plurality of emission reference directions in an emission wave region in which an emission wave being emitted from a plurality of emission reference directions and reaching a sensor spreads.

### Regarding Related Art of Fourth Example Embodiment

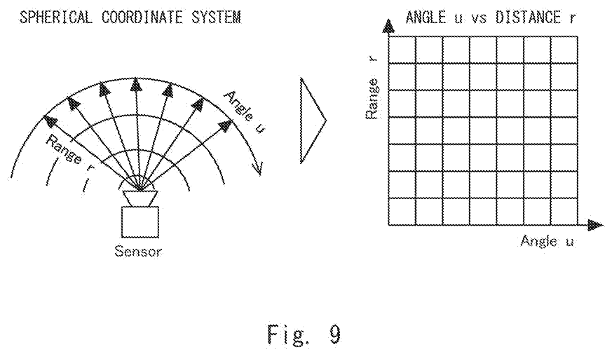

First, a spherical coordinate system will be described. FIG. 9 is a diagram for describing a spherical coordinate system.

In a left figure in FIG. 9, a scene in which an emission wave is emitted from a sensor is schematically illustrated. In the left figure in FIG. 9, an arrow represents an “emission reference direction” of an emission wave. That is, in the left figure in FIG. 9, a plurality of emission reference directions are illustrated. In the fourth example embodiment, a case in which, when the sensor emits an emission wave in one emission reference direction, the emission wave (beam width) spreads in a fan shape is assumed. Note that, in the following description, a region in which an emission wave emitted in one emission reference direction spreads may be referred to as an “emission wave unit region”. In addition, a region in which the emission wave unit regions for all emission reference directions are combined may be referred to as an “emission wave region”.

In the left figure in FIG. 9, an emission wave is schematically represented by a spherical coordinate system having a distance r and an angle u. Note that, in practice, an angle variable (for example, an angle v) is also present in a depth direction of a sheet of FIG. 9, but display is omitted herein. Hereinafter, description will be given with attention to the angle u, but an angle v direction is assumed to be equivalent to an angle u direction.

An emission wave reaching a sensor installed in a target space (training space) can be represented by a radial ray. Alternatively, an emission wave emitted from a sensor installed in a target space (training space) may be considered to be spread radially. When the emission wave is light, strictly speaking, the ray spreads in a fan shape (radial) manner. In addition, it can also be considered that intensity of light is attenuated by a distance, and that the intensity of the light is the same at the same distance r. For this reason, it may be more convenient to define a space in a spherical coordinate system than in an orthogonal coordinate system.

In order to simplify understanding of distribution calculation in the spherical coordinate system, in the following description, when plotting a graph, as illustrated in a right figure in FIG. 9, plotting is made by using an orthogonal coordinate system having an angle u as a horizontal axis and a distance r as a vertical axis. Note that, the graph appears at first glance to be an orthogonal coordinate system, but represents a spherical coordinate system.

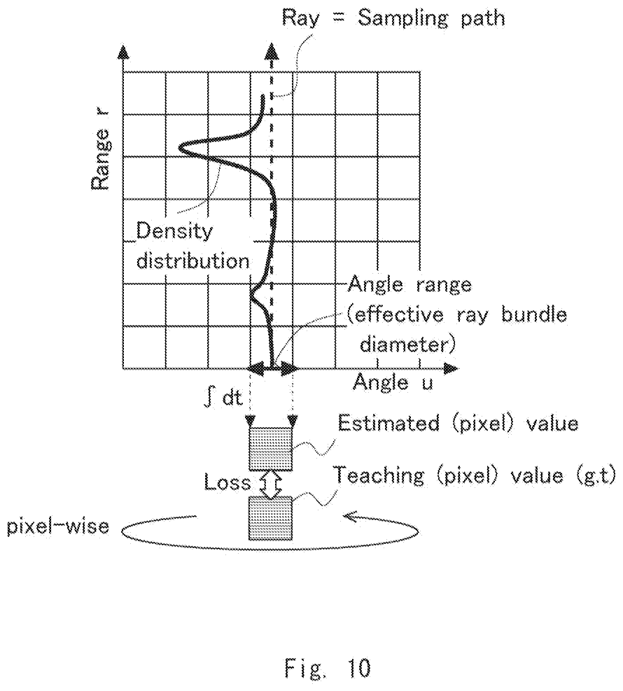

FIG. 10 is a diagram for describing a content of the related art described before the first example embodiment by using a spherical coordinate system.

FIG. 10 illustrates a density distribution acquired from an output of a training model. The training model receives information about positions of a plurality of sample points in a region to which a ray is received, and outputs a density distribution associated to the plurality of sample points. As illustrated in FIG. 10, the density distribution is performed line integration, and an estimated (pixel) value is acquired. A difference amount (loss) is calculated by comparing the estimated (pixel) value with a teaching (pixel) value.

A ray width at this time can be considered to be a width of the smallest step of an angle u axis. Then, the acquired density distribution can be interpreted as being acquired in a region that interferes with the ray width. Note that, repeatedly speaking, a “ray” herein is included in the emission wave of the present disclosure. In addition, in Non Patent Literature 1, a ray direction substantially coincides with a direction in which a sampling path extends. This is because estimation calculation (rendering) of the pixel value is performed by integrating density on the ray.

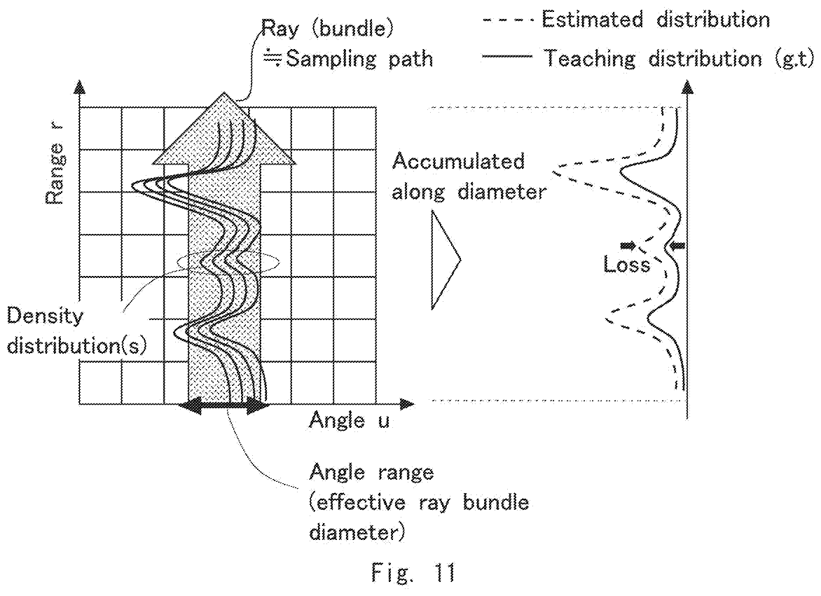

FIG. 11 is a diagram for describing a content of the first and second example embodiments by using a spherical coordinate system. A ray (ray bundle, emission wave) has a width wider than a predetermined level, and an interference width increases. As illustrated in a left figure in FIG. 11, a range in which the density distribution is acquired in an angle u direction is larger than that in the example in FIG. 10. In practice, a LiDAR signal having a finite ray bundle diameter has a value such that density associated to an object interfering with the ray bundle at the same distance r is integrated. When there is a step or slope of a structure in the ray bundle diameter, a value such as an average value of the density in a region corresponding to the step or slope of the structure is observed. This is synonymous with “blur” in a two-dimensional image. That is, when the ray bundle is large, an angular resolution decreases accordingly, and a signal is weakened. The acquired signal also becomes a signal being weakened as the ray bundle diameter is larger.

As illustrated in a right figure in FIG. 11, a difference amount (loss) is calculated by comparing a teaching distribution signal with an estimated distribution signal. By increasing the ray bundle diameter, a signal associated to a point of the distance r is weakened. However, with the configuration of the arithmetic operation system of the first example embodiment, since a distribution in a direction of the distance r is acquired, as illustrated in the right figure in FIG. 11, it is possible to perform comparison by using a signal distribution of one dimension.

### Regarding System of Fourth Example Embodiment

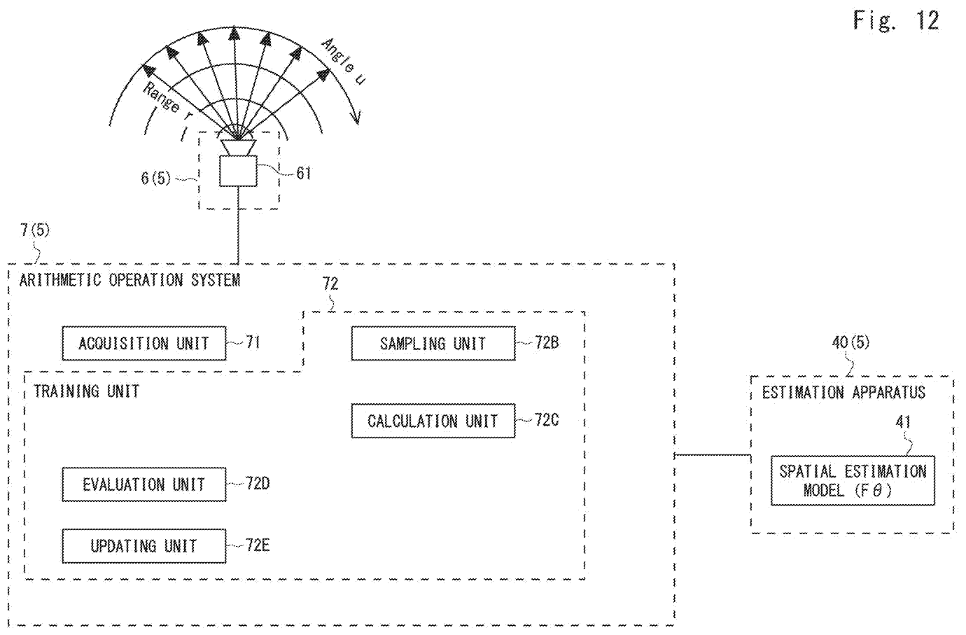

FIG. 12 is a block diagram illustrating one example of a system according to the fourth example embodiment. In FIG. 12, a system 5 includes an observation system 6, an arithmetic operation system 7, and an estimation apparatus 40. Note that, although one example of division of functions is illustrated in FIG. 12, a way of dividing the functions is not limited thereto. That is, functional units illustrated in FIG. 12 may be divided as appropriate, or may be aggregated in any combination. In addition, a way of distribution of each functional unit to the system or the apparatus in FIG. 12 is one example, and is not limited thereto. For example, the estimation apparatus 40 may be included in the arithmetic operation system 7. In addition, a plurality of functional units included in the arithmetic operation system 7 may be distributed to a plurality of independent apparatuses connected to each other.

### (Regarding Observation System)

In FIG. 12, the observation system 6 includes a sensor 61. The sensor 61 may be, for example, a LiDAR, a radar, or an acoustic sensor. Note that, although one sensor 61 is illustrated in FIG. 12, the observation system 6 includes a plurality of sensors 61.

Hereinafter, a description will be given on an assumption that a LiDAR is used for the sensor 61. Therefore, an emission region that interferes with a reception signal substantially coincides with an irradiation region, and an emission axis and an emission reference direction also coincide with an irradiation axis.

In addition, although not illustrated, a plurality of sensors 61 are arranged in such a way as to observe a subject from different viewpoints.

As described above, in the fourth example embodiment, a case where an irradiation wave (beam width) spreads in a fan shape when the sensor irradiates one emission reference direction with an irradiation wave is assumed. In a case where the sensor 61 is a LiDAR, when the sensor 61 irradiates one emission reference direction with an irradiation wave, the irradiation wave may be irradiated in an angle range of about 5° of a diffusion angle around the emission reference direction. Then, a reflected wave (emission wave) based on the irradiation wave is reflected in a range in which the beam width (irradiation wave) is approximately spread. Therefore, the region in which the beam spreads substantially coincides with an observation region. Note that, in the principle of the present example embodiment, since a kind of “wavefront” is handled even when a spread angle of the irradiation wave is wide, the diffusion angle may be 5° or more. In addition, in a case where the sensor 61 is a radar, when the sensor 61 irradiates one emission reference direction with an irradiation wave, the irradiation wave may be irradiated in an angle range of about 45° of a diffusion angle around the emission reference direction. In addition, in a case where the sensor 61 is an acoustic sensor, when the sensor 61 irradiates one emission reference direction with an irradiation wave, the irradiation wave may be irradiated in an angle range of about 180° of a diffusion angle around the emission reference direction. Magnitude of the diffusion angle may be appropriately determined by an effective diameter (effective spread angle) of an emission wave region observable by the sensor to be used.

Note that, in the first example embodiment, when a commercially available LiDAR is used as the sensor, it is assumed that a “one-dimensional signal of an intensity distribution with respect to a distance” being an internal intermediate signal is used as a teaching signal. On the other hand, in the fourth example embodiment, a signal of a commercially available LiDAR being equivalent to zero dimension can also be used.

(Regarding arithmetic operation system and estimation apparatus)

In FIG. 12, the arithmetic operation system 7 includes an acquisition unit 71 and a training unit 72. The training unit 72 includes a sampling unit 72B, a calculation unit 72C, an evaluation unit 72D, and an updating unit 72E. In FIG. 12, the estimation apparatus 40 stores a spatial estimation model 41. Note that, the sampling unit 72B and the calculation unit 72C are equivalent to a functional unit that performs “rendering” described above. That is, the sampling unit 72B and the calculation unit 72C are included in a “renderer”.

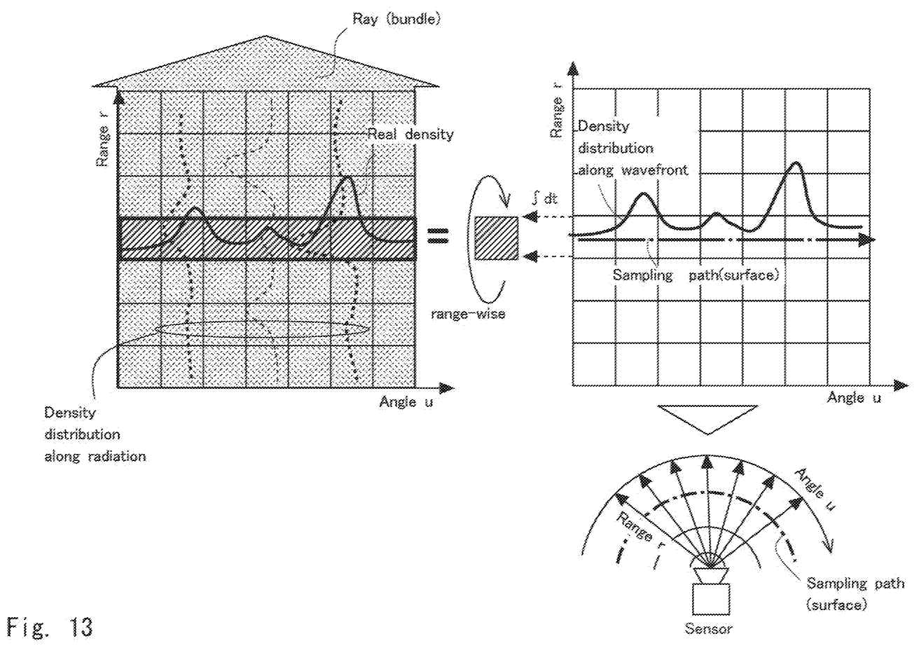

By irradiating an irradiation wave in a plurality of angular directions, the acquisition unit 71 acquires a signal of an “emission wave region” having a plurality of emission reference directions as an axis. For a spatial structure along a “region of interest” in each “emission wave region”, a spatial distribution signal observed by the sensor 61 via the emission wave is adopted as a teaching signal. Herein, the “region of interest” is a curved line region or a curved surface region intersecting with a plurality of emission reference directions. That is, a spatial structure along the “region of interest” as mentioned herein is equivalent to a curved line described as “Real density” in a left figure in FIG. 13, and the spatial distribution signal observed by the sensor 61 is equivalent to an integrated value in the angle u direction of the same curved line. FIG. 13 is a diagram for describing one example of processing operation of the training unit according to the fourth example embodiment.

The training unit 72 performs training of the spatial estimation model 41 by using the teaching signal.

Specifically, the sampling unit 72B inputs, to the spatial estimation model 41, information about a position of each of a plurality of sample points on the “region of interest” described above. For example, the sampling unit 72B inputs, to the spatial estimation model 41, information (for example, coordinates (u,r) of a sample point) about a sample point on a “Sampling path (surface)” in an upper right figure in FIG. 13. That is, in the fourth example embodiment, a direction in which the sampling region (in the fourth example embodiment, a region range of a target for integrating density) extends does not coincide with a ray direction (i.e., a direction parallel to an r axis in the upper right figure in FIG. 13).

With the input, the spatial estimation model 41 outputs estimated density related to a probability in which an object (i.e., a subject) reflecting an irradiation wave to a plurality of sample points is present. Then, the sampling unit 72B acquires the estimated density output from the spatial estimation model 41. As a result, the sampling unit 72B can acquire a correspondence relationship between the information about a position of each of the plurality of sample points and estimated density associated to each sample point.

The calculation unit 72C calculates an estimated signal (value) by integrating a plurality of pieces of estimated density associated to a plurality of sample points.

Herein, each row being parallel to the angle u axis in the left figure in FIG. 13 may be a region of interest. That is, a plurality of rows being parallel to the angle u axis are a plurality of regions of interest having different distances from the sensor 61 from each other. Therefore, the calculation unit 72C can form an estimated spatial distribution signal in a direction away from the sensor 61 by calculating an estimated signal value for each of the plurality of regions of interest. In addition, the angle u axis in the left and upper right figures in FIG. 13 is actually a spherical curved surface as illustrated in a lower right figure in FIG. 13. Therefore, in the fourth example embodiment, it can be interpreted that “wavefront representation” of a signal is used in training.

Note that, before integration processing, the calculation unit 72C may convert a plurality of pieces of estimated density (i.e., estimated density distributions) associated to each of a plurality of sample points, by physical calculation, similarly to the forming unit 32B of the first and second example embodiments. At this time, the calculation unit 72C calculates an estimated signal value by integrating the estimated density distribution after conversion.

The evaluation unit 72D calculates a difference amount, based on a teaching signal value and an estimated signal value. For example, the evaluation unit 72D may calculate the difference amount, based on the spatial distribution signal in the direction away from the sensor 61 and the estimated spatial distribution signal in the direction away from the sensor 61.

Further, signals from a plurality of viewpoints are summed together by acquiring and aggregating the difference amounts from the plurality of sensors 61 in the same manner. In the present example embodiment, since the sensor 61 does not have resolution in an angular direction, the spatial resolution decreases as a single sensor. Therefore, it is possible to increase estimation ability of the spatial structure by increasing the number of installed sensors 61 and increasing the difference signal from each viewpoint.

The updating unit 72E updates the spatial estimation model 41, based on the difference amounts. The updating unit 72E updates the spatial estimation model 41 in such a way that the difference amount becomes small. As a result, training of the spatial estimation model 41 advances.

### Example of Implementation

The simplest example of an implementation method of a technique of the fourth example embodiment is a method of defining a wavefront by setting a plurality of rays at high density, based on the method of Non Patent Literature 1.

By setting, to be dense, an angle step between rays of the plurality of rays to be defined, it is possible to approximate a ray bundle spreading in a fan shape as in the fourth example embodiment. The sampling unit 72B acquires an estimated intensity distribution of one dimension with respect to a distance for each of the plurality of dense rays. Then, the calculation unit 72C collects values of the estimated density of the same distance (equivalent to the same wavefront) of the plurality of rays (i.e., samples values on the estimated intensity distribution with respect to the distance in a wavefront direction), and integrates them. Then, since data are aggregated into single one-dimensional data, the evaluation unit 72D can use the data as an estimated intensity distribution in the wavefront representation (i.e., an estimated spatial distribution signal in the wavefront representation).

When sampling a density value on each of the rays at this time, the sampling unit 72B may use a conversion value that takes into consideration density around a sampling point. For example, when a value acquired by adding a weight according to a distance to each density of a density distribution in a direction perpendicular to a ray is added to a density value of a sampling point on the ray, it is equivalent to be setting a substantially “thick ray”. When a cross-sectional area of a certain extent size can be set for each of rays, the number of rays of a plurality of dense rays approximating the wavefront can be reduced, and an effect of reducing a calculation cost or memory consumption can be acquired. Note that, calculation taking into consideration the density distribution around the ray as described above is assumed to be equivalent when it is mathematically equivalent. For example, even when a mechanism in which a value of a peripheral coordinate is reflected in a high-dimensional vector array of position information converted by performing PE described above is introduced, a density value in which a diameter of the ray is taken into consideration is acquired in calculation.

As described above, according to the fourth example embodiment, since training can be executed by a signal in wavefront representation, the training and imaging of a spatial distribution can be performed even when the sensor using a medium having low directivity and close to the wavefront representation is used. For example, the present example embodiment can be applied to a sensor using an electric wave (a radar, a radio wave) or a sound wave. In addition, since the signal in the wavefront representation is used, a large number of difference amounts can be acquired as compared with Non Patent Literatures 1 and 2 (i.e., a case where a difference between a pixel value of teaching data and an estimated pixel value is acquired). Since the updating unit 72E can update the spatial estimation model, based on the large number of difference amounts, the training can be performed more efficiently.

### Modification Example (Application Example)

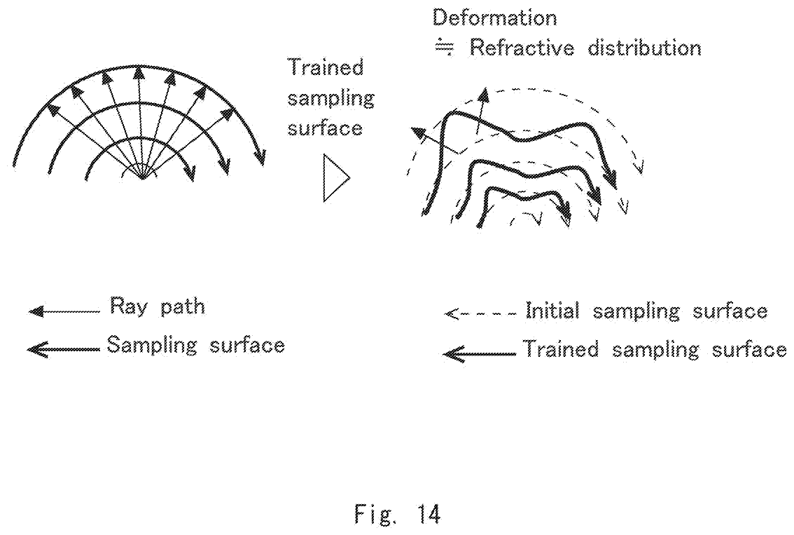

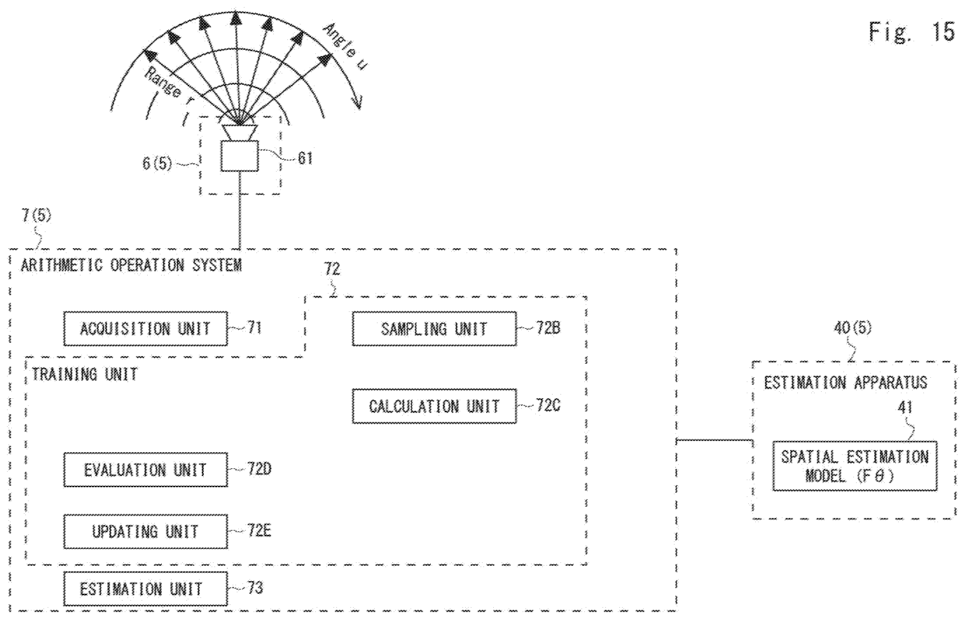

As a modification example (application example), a sampling region equivalent to a wavefront (i.e., the above-described region of interest) itself may be trained. FIG. 14 is a diagram for describing training of the sampling region. FIG. 15 is a diagram illustrating one example of a system according to a modification example of the fourth example embodiment.

In the fourth example embodiment, an estimated value along the wavefront is sampled, and for example, a wavefront region (region of interest) is represented by a function that can be trained by a parameter. Herein, the function is referred to as a “wavefront (region of interest) definition function”. An initial value of the wavefront definition function may be set in such a way as to be a spherical surface centered on a viewpoint of the sensor 61 (refer to a left figure in FIG. 14). According to a differentiable rendering method, when training is advanced in a state where the wavefront definition function is also connected to a calculation graph, a parameter of the wavefront definition function is updated in such a way as to represent a wavefront closer to reality in a course of optimization. For example, casting a LiDAR ray to an air layer having a temperature distribution is considered. At this time, as illustrated in a right figure in FIG. 14, a wavefront deviated from a spherical surface may be formed. This means that distortion of the wavefront of an emission wave is visible. That is, this is equivalent to acquiring a refractive index distribution for an emission wave (herein, light) in a space. That is, by using the method of the modification example of the fourth example embodiment, it is possible to indirectly acquire a distribution of an attribute (herein, the refractive index) of a spatial medium (air in this example), which is not acquired as an intensity signal of the ray.

In addition, in the fourth example embodiment, the sampling region (in particular, an integration region of the sampling region) is defined as a spherical region, but the present example is not limited thereto. For example, a shape of the sampling region can be appropriately changed according to a physical propagation model of an emission wave received by the sensor 61 and a form of a reception signal. For example, when the sensor 61 simultaneously receives a signal spreading in an ellipse, the shape of the sampling region may be an ellipse. When the emission wave of the sensor 61 can be expressed by a plane wave, the shape of the sampling region may be defined by a plane. In addition, the shape of the sampling region may be a shape of a complicated wavefront approximated by a polynomial.

In the modification example of the fourth example embodiment, the arithmetic operation system 7 further includes an estimation unit 73. As described above, the wavefront (region of interest) definition function is connected to the calculation graph of the training unit 72. The updating unit 72E updates a parameter of the wavefront (region of interest) definition function, based on a difference amount acquired by the evaluation unit 72D.

The estimation unit 73 estimates the refractive index distribution for the emission wave in the space, based on the shape of the wavefront region (region of interest) expressed by the function, by using the wavefront (region of interest) definition function whose parameter is optimized.

### Other Example Embodiment

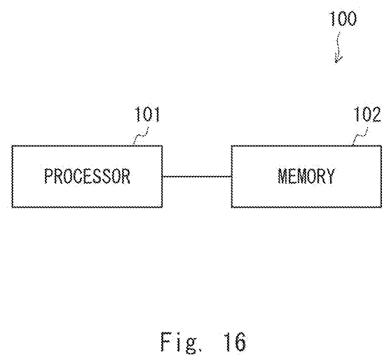

FIG. 16 is a diagram illustrating a hardware configuration example of an arithmetic operation system. In FIG. 16, an arithmetic operation system 100 includes a processor 101 and a memory 102. The processor 101 may be, for example, a microprocessor, a micro processing unit (MPU), or a central processing unit (CPU). The processor 101 may include a plurality of processors. The memory 102 is configured by a combination of a volatile memory and a non-volatile memory. The memory 102 may include a storage arranged away from the processor 101. In this case, the processor 101 may access the memory 102 via a not-illustrated input/output (I/O) interface.

Each of the arithmetic operation systems 3 and 7 of the first to fourth example embodiments can have a hardware configuration illustrated in FIG. 16. The acquisition units 31, 34, and 71, the training units 32, 33, 35, and 72, and the estimation unit 73 of the arithmetic operation systems 3 and 7 according to the first to fourth example embodiments may be achieved by the processor 101 reading and executing a program stored in the memory 102. The program can be stored and provided to the arithmetic operation systems 3 and 7 using any type of non-transitory computer readable media. Non-transitory computer readable media include any type of tangible storage media. Examples of non-transitory computer readable media include magnetic storage media (such as floppy disks, magnetic tapes, hard disk drives, etc.), optical magnetic storage media (e.g., magneto-optical disks), CD-ROM (compact disc read only memory), CD-R (compact disc recordable), CD-R/W (compact disc rewritable), and semiconductor memories (such as mask ROM, PROM (programmable ROM), EPROM (erasable PROM), flash ROM, RAM (random access memory), etc.). The program may be provided to the arithmetic operation systems 3 and 7 using any type of transitory computer readable media. Examples of transitory computer readable media include electric signals, optical signals, and electromagnetic waves. Transitory computer readable media can provide the program to the arithmetic operation systems 3 and 7 via a wired communication line (e.g., electric wires, and optical fibers) or a wireless communication line.

According to the present disclosure, it is possible to provide an arithmetic operation system, a training method, and a training program that contribute to solving at least one of a plurality of problems including the problems described above.

While the disclosure has been particularly shown and described with reference to example embodiments thereof, the disclosure is not limited to these example embodiments. It will be understood by those of ordinary skill in the art that various changes in form and details may be made therein without departing from the spirit and scope of the present disclosure as defined by the claims. Each example embodiment can be combined with another example embodiment as appropriate.

What is claimed is:

1. An arithmetic operation system comprising:
at least one memory configured to store instructions; and
at least one processor configured to execute, according to the instructions, a process comprising:
acquiring, as a teaching signal, a spatial distribution signal observed by a sensor with respect to a spatial structure on a path of an emission wave by using the emission wave;
inputting information about a position of each of a plurality of sample points on the path to a spatial estimation model, and acquiring, from the spatial estimation model, estimated density related to a probability that an object emitting the emission wave from the plurality of sample points is present;
forming an estimated signal for comparing with the teaching signal, based on information about a position of each of the plurality of sample points and estimated density of each of the plurality of sample points;
calculating a difference amount between the teaching signal and the estimated signal; and
updating the spatial estimation model, based on the difference amount.

2. The arithmetic operation system according to claim 1, wherein the spatial distribution signal is a signal representing intensity of an emission wave at each point with respect to a distance from a reference point to each point on the path, the distance being acquired based on an emission wave emitted on the path.

3. The arithmetic operation system according to claim 1, wherein the spatial distribution signal is a signal observed by light detection and ranging (LiDAR).

4. The arithmetic operation system according to claim 2, wherein
the emission wave is emitted from a reference direction toward the reference point, and
the plurality of sample points includes a plurality of main sample points on a straight line extending from the reference point to the reference direction, and a plurality of sub sample points being in an emission wave region extending in a direction orthogonal to the straight line and deviating from the straight line.

5. The arithmetic operation system according to claim 1, wherein the forming includes converting, into a form of a spatial distribution, a relationship between information about a position of each of the plurality of sample points and estimated density of each of the plurality of sample points.

6. The arithmetic operation system according to claim 1, wherein a step of a reception direction being separable by the sensor is smaller than a diameter of an effective region of the emission wave.

7. A training method to be executed by an arithmetic operation system, the training method comprising:
acquiring, as a teaching signal, a spatial distribution signal observed by a sensor with respect to a spatial structure on a path of an emission wave by using the emission wave;
inputting information about a position of each of a plurality of sample points on the path to a spatial estimation model, and acquiring, from the spatial estimation model, estimated density related to a probability that an object emitting the emission wave from the plurality of sample points is present;
forming an estimated signal for comparing with the teaching signal, based on information about a position of each of the plurality of sample points and estimated density of each of the plurality of sample points;
calculating a difference amount between the teaching signal and the estimated signal; and
updating the spatial estimation model, based on the difference amount.

8. The training method according to claim 7, wherein the spatial distribution signal is a signal representing intensity of an emission wave at each point with respect to a distance from a reference point to each point on the path, the distance being acquired based on an emission wave emitted on the path.

9. A non-transitory computer readable medium storing a training program causing an arithmetic operation system to execute processing including:
acquiring, as a teaching signal, a spatial distribution signal observed by a sensor with respect to a spatial structure on a path of an emission wave by using the emission wave;
inputting information about a position of each of a plurality of sample points on the path to a spatial estimation model, and acquiring, from the spatial estimation model, estimated density related to a probability that an object emitting the emission wave from the plurality of sample points is present;
forming an estimated signal for comparing with the teaching signal, based on information about a position of each of the plurality of sample points and estimated density of each of the plurality of sample points;
calculating a difference amount between the teaching signal and the estimated signal; and
updating the spatial estimation model, based on the difference amount.

10. The non-transitory computer readable medium according to claim 9, wherein the spatial distribution signal is a signal representing intensity of an emission wave at each point with respect to a distance from a reference point to each point on the path, the distance being acquired based on an emission wave emitted on the path.
